(19) United States
(12) Patent Application Publication
(10) Pub. No.: US 2003/0094239 A1
(43) Pub. Date: May 22, 2003

(54) Apparatus and method for improving electron ecceleration

(76) Inventors: Bill H. Quon, Brea, CA (US); Jovan Jevtic, Milwaukee, WI (US); Thomas H. Windhorn, Mesa, AZ (US); Wayne L. Johnson, Phoenix, AZ (US)

Correspondence Address: PILLSBURY WINTHROP, LLP, P.O. BOX 10500, MCLEAN, VA, 22102, US

(21) Appl. No.: 10/307,484

(22) Filed: Dec. 2, 2002

Related U.S. Application Data
(63) Continuation of application No. PCT/US01/17190, filed on May 29, 2001.
(60) Provisional application No. 60/208,568, filed on Jun. 2, 2000.

(51) Int. Cl. H01L 21/306; C23C 16/00

(52) U.S. Cl. 156/345.51; 118/723 R; 118/728

(57) ABSTRACT

Apparatus and method for supplying a bias voltage to a wafer chuck in a plasma reactor system, in which an RF voltage source produces a relatively low frequency RF voltage, a VHF voltage source produces a VHF voltage having a higher frequency than the RF voltage, and a coupling circuit connected between the RF and VHF voltage sources and the wafer chuck combines the RF and VHF voltages for application to the wafer chuck.

This is a continuation of International Application No. PCT/US01/17190, which was filed on May 29, 2001, and also claims benefit of U.S. Application No. 60/208,568, filed Jun. 2, 2000, the contents of both of which are incorporated herein in their entirety.

### BACKGROUND OF THE INVENTION

The present invention relates to semiconductor wafer fabrication using plasma assisted processes.

Semiconductor wafer fabrication procedures generally include etching, layer deposition and chemical treatments that alter the composition of the wafer surface or portions thereof. All of these procedures may be performed selectively, i.e. on a portion of the wafer surface according to a defined pattern while the wafer is mounted on a chuck in a plasma processing chamber.

Wafer fabricators are constantly seeking to reduce the time required to carry out such procedures and, at the same time, to improve product quality and reduce the reject rate.

Selective etching operations generally involve etching relatively narrow and deep grooves and contact holes and one of the obstacles to achieving etching rate increases is the tendency to produce shading damage. Shading damage, otherwise referred to as pattern-dependent charging damage, is caused when the upper surfaces of topographical substrate features such as contact holes, vias and capacitor trenches electrically shade the bottoms of these features from a balanced flow of the ions and electrons. Early arriving electrons accumulate at the top of the substrate topography until the area becomes negatively charged, whereupon electrons which arrive later are then rejected or repelled. Due to the Coulomb forces, the trajectories of the later arriving electrons will be altered by the negative charges accumulated at the top of these features. As a result, these later arriving electrons can not reach the bottom of high aspect ratio features. On the other hand ions are accelerated down into the features and accumulate at the bottoms, which thus become positively charged. Furthermore, the electrons that do manage to penetrate the feature are preferentially deflected towards the inner walls of the feature due to their low inertia, while more of the relatively massive ions can reach the feature bottom due to their large inertia.

As electrons build up at the tops and ions at the bottoms of substrate features, a relatively negative charge accumulates at the tops of features while a relatively positive charge accumulates at the feature bottoms. This charging phenomenon becomes a significant problem particularly when a thin oxide layer, used to form MOS-FET gate insulation, resides at the bottom of the etched feature. Therein, the potential difference between the accumulated positive charge at the bottom of the etched feature and the underlying silicon substrate becomes sufficiently large to cause a large positive current, ultimately leading to the breakdown of the thin oxide layer. Consequently, shading damage has been identified by semiconductor manufacturers as a major problem. As the industry goes to thinner and thinner oxide layers, shading damage will become more of a problem. Moreover, the problem is only further exacerbated with the drive to increase the plasma density in order to increase the etch rate.

It is currently believed that using energetic electrons from the plasma can effectively reduce the shading damage. Alternatively, accelerating electrons from the plasma to the wafer surface can be an effective means as well. It is common practice in this art to apply a relatively low frequency RF bias voltage to the wafer to create a self-bias that will attract ions to the wafer. However, in order to prevent shading damage, it is necessary to deposit enough electrons at the bottoms of the grooves and holes for every low frequency RF bias cycle to balance the positive ion charges there.

It is a relatively easy task to accelerate positive ions to the wafer by providing a suitable negative bias voltage on the chuck, such as that produced by the above-mentioned low frequency RF bias voltage. However, accelerating electrons to the wafer will need more sophisticated techniques. Any method for drawing electrons from plasma must consider the source impedance of the plasma, commonly referred to as the current-voltage (I-V) characteristic of the charging source (wherein the plasma can be referred to as a charging source). The electron current flowing into a chuck increases dramatically as an exponential function of the chuck bias voltage. This can be expressed by the equation:

I=Iₛe^{+e(V-Vs)/Te}

where I is the electron current, Iₛ is the electron saturation current, e is the electron charge, Tₑ is the electron temperature in electron volts, V is the bias voltage on the chuck and Vₛ is the plasma potential. The electron current will become very large if the chuck bias voltage V approaches the plasma potential Vₛ. When the electron current is substantially greater than the ion saturation current, the plasma will be charged up. When that happens the plasma will act as a high impedance current source for the electron current. When the plasma current source is overdrawn the plasma potential collapses to the electrode potential, the electrons then will flood the wafer with very little energy and would only increase the space charge without having enough energy to go into the bottoms of high aspect ratio features.

The latter result will occur if a positive bias voltage is simply applied to the chuck in such a manner that the plasma potential would follow closely to the most positive voltage on the chuck, in which case the positive bias voltage on the chuck will simply raise the plasma potential. It has previously been proposed, as disclosed in Japanese Patent No. 10270419, to impart such energy to electrons, and thus reduce shading damage, by adding short duration positive bias voltage pulses to the low frequency RF bias voltage applied to the chuck, as shown in FIG. 1A. In order to accelerate electrons to the wafer, each pulse is imposed upon a positive half cycle of the low frequency RF bias. Each pulse must have a precise phase or time delay with respect to the low frequency RF bias voltage on the chuck in order to accelerate the electrons with each positive pulse and to accelerate the ions with the negative low frequency RF voltage during other parts of each RF voltage cycle. The precise timing of each pulse is critical in this method. The above-cited patent discloses that in order to accelerate the electrons by each positive pulse voltage on the chuck, the pulse duration, or width, must be smaller than the response time of the plasma potential and that a pulse duration of 10 ns will be fast enough to accelerate the electrons toward the wafer without raising the plasma potential.

In general, in order for the plasma ions in the sheath to synchronize with the relatively low frequency RF voltage on the chuck and be redistributed within each RF period, the RF voltage must have a frequency lower than the frequency which excites and maintains the plasma. Thus, the upper frequency limit for the RF voltage is the plasma excitation frequency. The lower frequency limit for the RF voltage is determined by the maximum charging time (t_{c}) to which the wafer can be exposed in the plasma without causing shading damage, namely, f>1/t_{c}. The term “charging time” is recognized in the art. Therefore, the frequency range for the relatively low frequency RF bias voltage on the chuck in general is in the range of several hundreds of KHz to a few MHz.

The RF bias voltage is usually coupled to the chuck by using DC blocking capacitors. This will allow a DC self-bias to develop on the chuck surface. This self-bias voltage on the chuck surface is uniquely determined when there is a zero net current to the surface over one chuck bias voltage cycle, i.e. there exists the condition of an equality of electron and ion current at the surface (for further details, see Phys. Fluids 6, pp. 1346-, 1963). The electron current will reach a maximum at the peak of the RF bias voltage and remains negligibly small during the rest of the RF bias voltage cycle.

In a plasma-assisted process of the type to which this invention is applicable, the plasma in the processing chamber can be treated as being enclosed by a boundary surface. One such surface is the wafer surface being processed, to which the RF bias voltage is coupled and upon which the DC self-bias is formed. At this physical surface, an electrical boundary layer, or sheath, is formed, across which the electrical potential varies from the potential at the plasma space to the potential at the physical surface (assuming, for simplicity, any weak potential variation across the “pre-sheath” can be neglected). FIG. 2C illustrates the waveforms of voltages at the edge of the plasma Vₚ(t) and at the wafer surface V_{b}(t). The negative offset of the bias voltage waveform represents the DC self-bias voltage V_{dc}. Therefore, an instantaneous potential profile at the wafer surface during the peak of the RF bias voltage waveform (line 2A in FIG. 2C) and at a time later than the waveform peak (line 2B in FIG. 2C) are shown in solid lines in FIGS. 2A and 2B, respectively. In FIG. 2A, the instantaneous voltage is approximately constant from the plasma to the wafer surface, i.e. the plasma sheath has collapsed. However, in FIG. 2B, the voltage monotonically decreases across the sheath to the wafer surface.

Now, in the case when a voltage pulse as shown in FIG. 1A is superposed on the sinusoidal bias voltage waveform, the potential profile behaves differently depending upon when the pulse is applied during the bias voltage wave cycle. For example, as shown in FIG. 2A, a square wave voltage pulse between the times of t₁ and t₄ superposed at the bias voltage peak will result in an increase to the plasma space potential during the duration of the pulse. During this time, the wafer surface receives a flood of low energy electrons (thus the reason for the increase in the plasma space potential); when the surface potential is pulsed positive, the very mobile (low inertia) electrons flood the surface due to the briefly existing electric attraction and subsequently raise the plasma space potential to maintain zero net current flow. However, if the pulse is superposed at an optimal location off the peak of the bias voltage waveform, the potential distribution may respond differently as shown in FIG. 2B. If the pulse is sufficiently fast (i.e 1-10 ns), then the plasma space potential will remain unchanged and the voltage distribution will no longer be monotonically decreasing across the sheath to the wafer surface, but rather decreases to a trough and then increases to the pulse voltage magnitude at the wafer surface, as shown by the broken line in FIG. 2B). Under this condition, electrons arriving at the sheath edge whose kinetic energy is less than the potential energy barrier given by eΔV (where e is the electric charge and ΔV is the potential difference between the plasma space potential and the sheath voltage trough) will be repelled back towards the plasma, whereas those electrons whose kinetic energy is greater than the potential energy barrier will penetrate into the sheath and be further accelerated to the wafer surface. By this means, only the high energy electrons (whose numbers are few in the plasma electron energy distribution) penetrate the sheath in order to be further accelerated to the wafer surface. These electrons are then of sufficiently high energy to penetrate the high aspect ratio features and balance the accumulated positive charge at the feature bottoms.

A critical factor in the method disclosed in the above-cited patent is the timing control of each pulse with respect to the corresponding RF bias voltage peak. As stated above, if the pulse starts too early, the RF bias voltage is too close to the plasma potential and may overdraw the plasma current, which causes the plasma potential to rise with the pulse voltage. As a result, electrons at the plasma sheath edge will not gain any energy. On the other hand, if the pulse starts too late, at a point where the RF bias voltage is too negative, there will be very few electrons reaching the plasma boundary and very few energetic electrons will be generated. Effective timing control for the method described in the patent is very difficult to achieve, and because the plasma potential and electron energy both change rapidly as the plasma and other process conditions vary in industrial processes, that method is not well suited for use on an industrial scale.

### BRIEF SUMMARY OF THE INVENTION

The present invention provides an apparatus and a method for selectively accelerating electrons in a plasma system by using a chuck bias voltage composed of a very high frequency (VHF) sinusoidal voltage superposed on a low frequency RF voltage. It has been found that such a chuck bias voltage can selectively accelerate electrons to the wafer surface. This bias will further accelerate the electrons to a higher energy so that they can reach the bottoms of high aspect ratio contact holes and narrow grooves in the wafer patterns. The result will be to effectively reduce shading damage.

### BRIEF DESCRIPTION OF THE SEVERAL VIEWS OF THE DRAWING

FIGS. 1A and 1B are waveform diagrams showing chuck bias voltages according to the prior art (FIG. 1A) and according to the present invention (FIG. 1B).

FIGS. 2A, 2B and 2C are waveform diagrams showing the instantaneous spatial voltage profile during a pulse at the bias voltage peak (FIG. 2A), the instantaneous spatial voltage profile during a pulse shifted off the bias voltage peak (FIG. 2B), and the instantaneous plasma and bias voltages (FIG. 2C).

FIG. 3A is a circuit diagram illustrating a first embodiment of the invention,

FIG. 3B is a circuit diagram illustrating a second embodiment of the invention, and FIG. 3C is a circuit diagram illustrating a third embodiment of the invention.

FIGS. 4A, 4B and 4C are circuit diagrams of alternative forms of construction for one component of each of the circuits of FIGS. 3A and 3B.

### DETAILED DESCRIPTION OF THE INVENTION

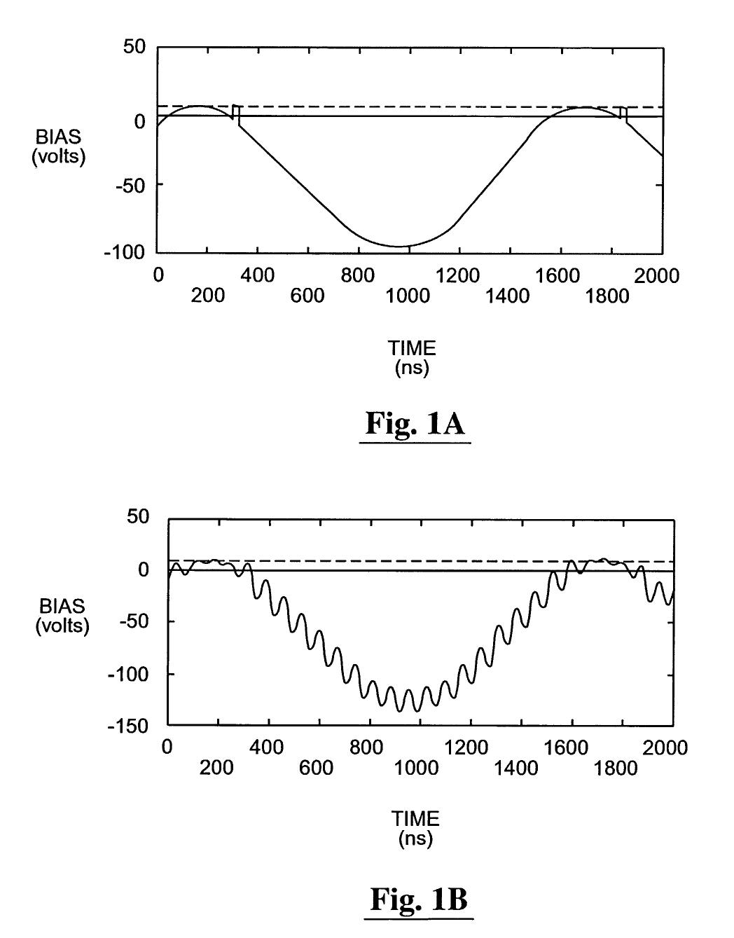

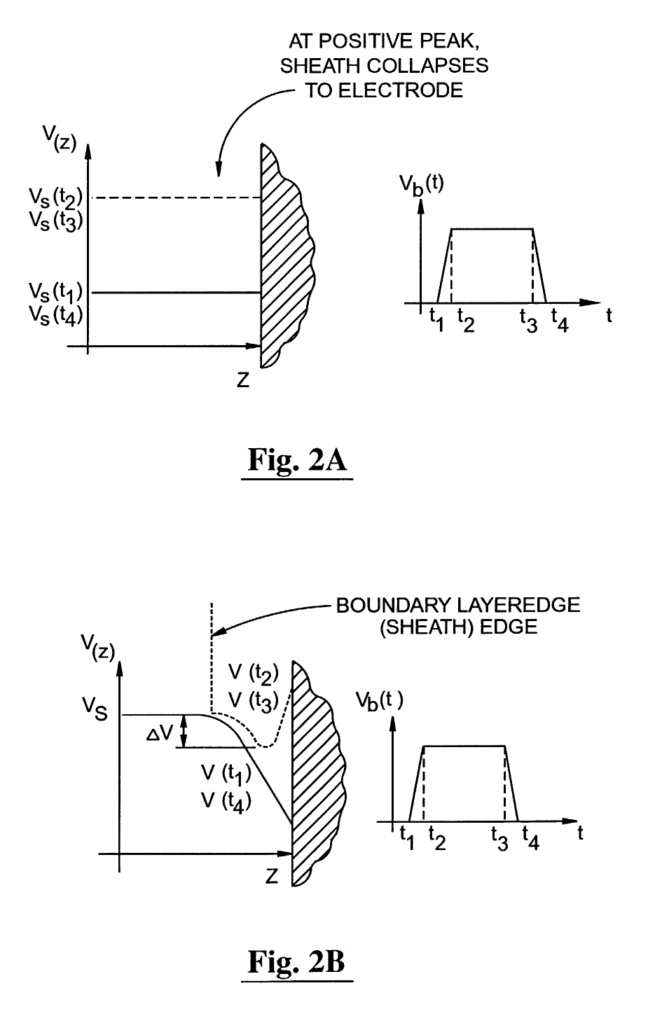

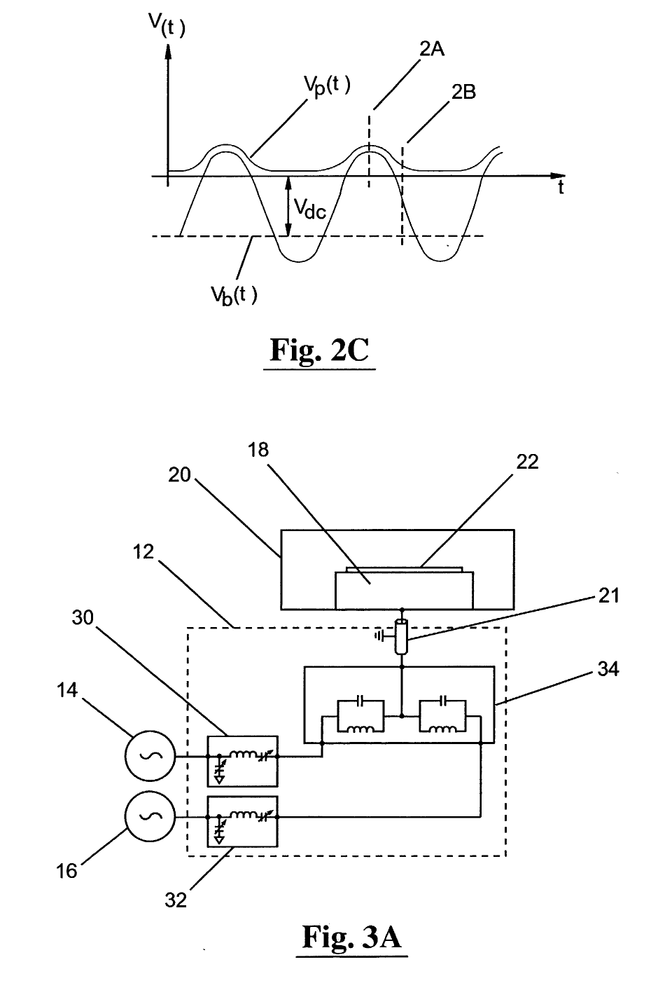

According to the present invention, instead of using a positive pulse voltage as employed in the prior art, a very high frequency (VHF), preferably sinusoidal, voltage oscillation is superposed on a RF bias voltage having a relatively low frequency in the RF range and hence referred to hereinafter as a low frequency RF voltage. Thus the total chuck bias voltage consists of a VHF sinusoidal voltage superposed on the entire low frequency RF bias voltage wave, as shown in FIG. 1B. The VHF voltage oscillation inherently provides a short duration positive voltage at a point close to each positive peak of the RF voltage oscillation to assure that an electron acceleration phase will occur during each RF cycle without requiring a complex pulse timing system.

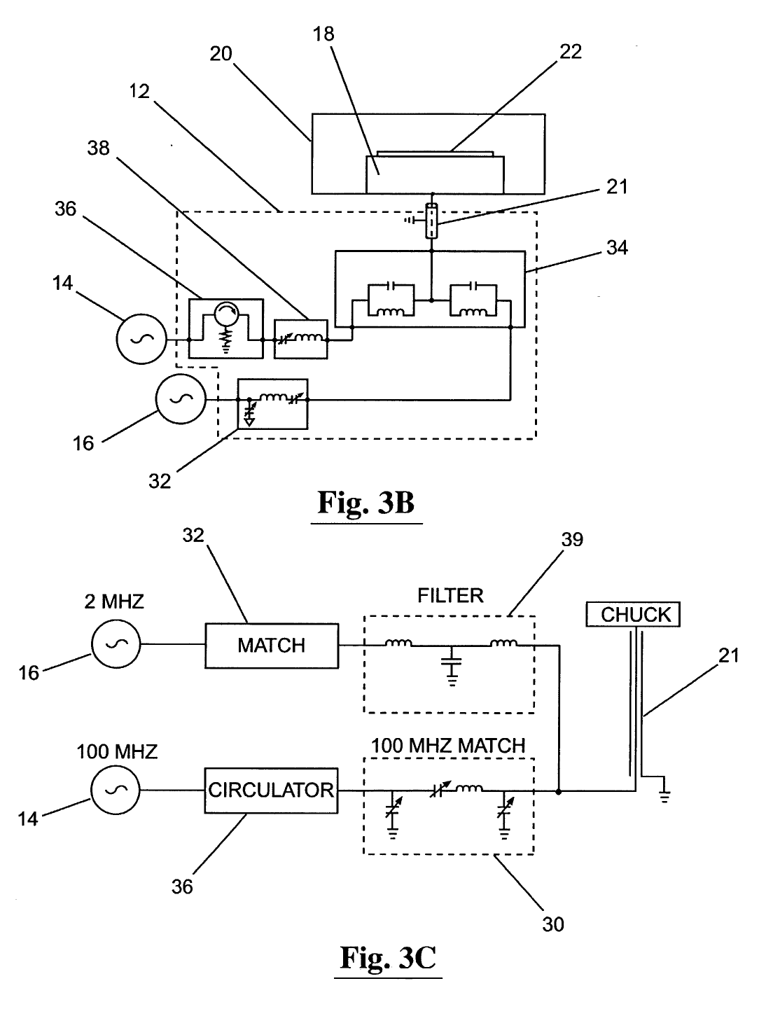

According to one preferred embodiment of the invention, the voltage waveform of FIG. 1B, in which both the RF and the VHF components are sinusoidal, can be provided by the circuit arrangement shown in FIG. 3A. This is a coupling circuit 12 capable of combining the VHF and RF signals at the chuck while maintaining an impedance match between the VHF and RF power generators and the load. Coupling circuit 12 is connected between a very high frequency (VHF) generator 14, a low frequency RF generator 16 and a chuck 18 of a plasma reactor system 20. Coupling circuit 12 is electrically connected to chuck 18 via a transmission line 21. Chuck 18 supports a wafer 22 that is to undergo a plasma assisted fabrication process. Chuck 18, wafer 22 and the plasma in system 20 form the load impedance for circuit 12. Plasma reactor system 20 can be of any known type constructed to produce a plasma for carrying out a wafer fabrication process. Such a system can employ components which produce an inductively coupled or capacitively coupled plasma.

The illustrated embodiment of coupling circuit 12 is composed of a VHF match network 30, a low frequency RF match network 32 and a VHF-RF combiner circuit 34. VHF match network 30 is specifically designed for matching the output impedance of VHF generator 14 to the load impedance (at the VHF frequency). For example, match network 30 may be an L-type network with an inductor in series with a variable capacitor and a second variable capacitor to ground. RF match network 32 is specifically designed for matching the output impedance of RF generator 16 to the load impedance (at the RF frequency). Similarly, match network 32 may be an L-type network as shown. RF-VHF combiner circuit 34 adds (or superposes) the respective RF and VHF signals, wherein a filter in the circuit leg attached to VHF match network 30 is designed to reject the RF signal (i.e. isolate VHF generator 14 from RF power) and a filter in the circuit leg attached to RF match network 32 is designed to reject the VHF signal (i.e. isolate RF generator 16 from VHF power). With this circuit, one may superpose a “matched” VHF signal on a “matched” RF signal and apply the resultant signal to the chuck. The power delivered from VHF generator 14 and RF generator 16 may be independently varied.

FIG. 3B presents an alternative embodiment wherein the impedance of the VHF leg of the coupling circuit may be independently varied. This second embodiment is again composed of a VHF coupling portion and a RF coupling portion. The VHF coupling portion is composed of an isolator 36 and a variable impedance circuit 38. Isolator 36 may comprise a circulator and a load resistor as shown in FIG. 3B, and is required to dissipate reflected power that would otherwise be directed to VHF generator 14. Since the output impedance of VHF generator 14 is not itself impedance matched to the load, i.e., VHF match network 30 is not present in the circuit of FIG. 3B, VHF power will be reflected back towards VHF generator 14. The circulator protects the generator and dumps the power to a resistor. Variable impedance circuit 38 facilitates either manual or automatic control of the impedance of the VHF leg of the coupling circuit, and may in one form simply comprise a variable capacitor. This variable capacitor could in one sense be use to reactively counter the inductance associated with transmission line 21. As before, the RF coupling portion includes a match network 32 connected to the output of RF generator 16 and to the input of combiner circuit 34.

FIG. 3C presents a third embodiment, which combines the advantages of the first and second embodiments described above. The VHF coupling portion includes a circulator 36 between the VHF generator 14 and a match network 30. Match network 30 can serve to maximize VHF power transfer and circulator 36 can protect VHF generator 14 from high frequency noise generated in the plasma. For example, this high frequency noise can be presented to the chuck circuit as the low frequency side-bands around the VHF carrier. In replacement of the L-type match network, a p-type match network is included in this embodiment with additional variable capacitance to counter the large inductance of the transmission line 21. The low frequency coupling portion is similar to that in FIG. 3A, except a “sharp” T-type filter 39 is included for isolating the VHF power without using a combiner 34.

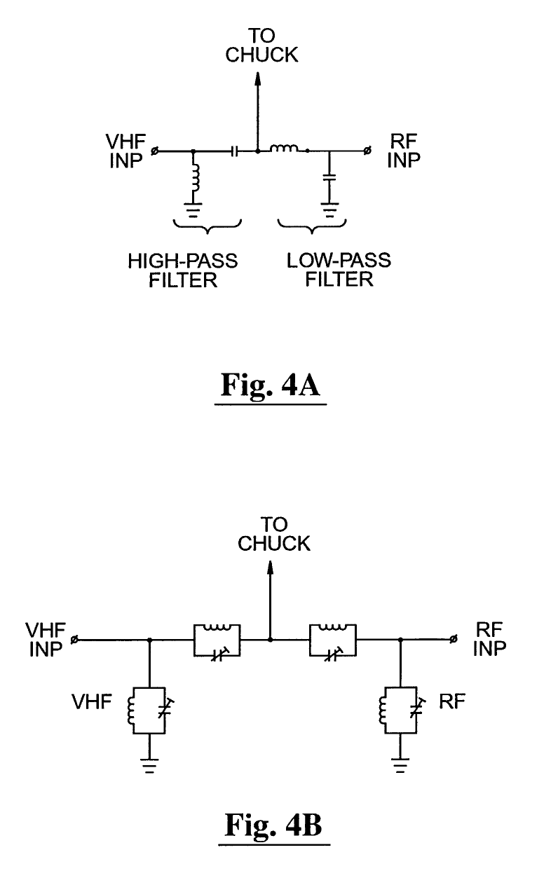

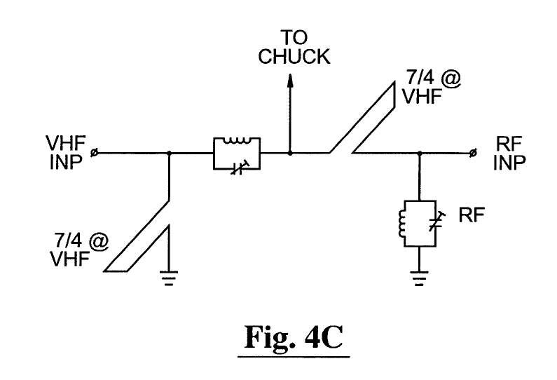

In the circuits shown in FIGS. 3A and 3B, combiner circuit 34 is composed of two parallel resonant filters. However, other circuit configurations are also possible, three examples of which being shown in FIGS. 4A, 4B and 4C. The combiner circuit of FIG. 4A is composed of a low-pass filter connected in the RF circuit path and dimensioned to pass the RF voltage and block the VHF voltage, and a high-pass filter connected in the VHF circuit path and dimensioned to pass the VHF voltage and block the RF voltage. The combiner circuit of FIG. 4B is composed of a parallel resonant circuit connected in series in the RF circuit path to pass the RF voltage and block the VHF voltage, a parallel resonant circuit connected in shunt with the RF circuit path to block the RF voltage and pass any VHF voltage that may be present, a parallel resonant circuit connected in series in the VHF circuit path to pass the VHF voltage and block the RF voltage, and a parallel resonant circuit connected in shunt with the VHF circuit path to block the VHF voltage and pass any RF voltage that may be present. The combiner circuit of FIG. 4C is composed of a VHF quarter wavelength transmission line connected in series in the RF circuit path to pass the RF voltage and to act as an open circuit for the VHF voltage, a parallel resonant circuit connected in series in the VHF circuit path to pass the VHF voltage and block the RF voltage, and a VHF quarter wavelength transmission line connected in shunt with the VHF circuit path to block the VHF voltage and to act as a short circuit for any RF voltage that may be present.

The VHF voltage used in the preferred embodiment is a sinusoidal voltage in the frequency range of one hundred to several hundred MHz, but it can have other waveforms and frequencies. Low frequency RF generator 16 supplies a low frequency RF voltage preferably in the frequency range of several hundreds of KHz to several MHz to circuit 12, but this voltage can have other values. VHF generator 14 can require up to 1 kW power and RF generator 16 can require up to 3 kW power.

FIGS. 1A and 1B show a comparison of the timing programs between a pulsed chuck bias (FIG. 1A) according to the prior art and a sinusoidal VHF chuck bias (FIG. 1B) according to the present invention. In FIG. 1A, for the pulsed chuck bias, the pulse level and timing control are critical. In FIG. 1B, for the sinusoidal VHF chuck bias, impedance and magnitude variation of the VHF voltage may be required, but no timing control is needed.

The impedance and magnitude control of the VHF voltage can be accomplished manually or automatically at the coupling circuit. These control values may be determined by experimental testing. Once the road map for all supported processes has been established, the operator of the processing installation, or system, can manually or automatically set up the corresponding mode for a particular process to achieve a maximum etch rate with minimum damage.

The electron current is highest at the positive peaks of the low frequency RF voltage, where, by using coupling circuit 12, the magnitude of the superposed VHF voltage is attenuated to almost zero at the positive peaks of the low frequency RF voltage, as shown in FIG. 1B. A first substantially unattenuated peak of the VHF voltage appears near the positive peak, and on the descending slope, of the low frequency RF voltage, where it is most effective to produce an electron acceleration phase. The coupling circuit should not be limited to the design in the preferred embodiment. There are many variations on the circuit design that can be used to perform the task described above.

A particular characteristic of circuit 12 is that its output impedance for the VHF voltage is very high (>>50Ω). When this VHF voltage is supplied to chuck 18, it will be automatically attenuated if the electron current to chuck 18 becomes too high; i.e. it acts as a current source due to the fact that the current through the coupling circuit increases and thus the voltage drop in the coupling circuit increases. The superposition of the VHF signal on the RF signal should have little effect on the ion energy since the VHF frequency is sufficiently higher than the ion frequency, i e., the ion inertia is too great to follow the VHF field. The sinusoidal VHF voltage thus functions as a train of pulses. When the VHF voltage is combined with the low frequency RF voltage and supplied to the chuck bias, there will always be one or several positive half-cycles of the VHF voltage occurring at the right time to accelerate the electrons. The other VHF positive half-cycles will have a minimal effect on the operation of the system.

The invention further provides a method for finding the optimal source impedance for a given process. The procedures for finding the optimal impedance for a given process can be described as follows: during the process, the operator can observe the waveforms of both the VHF sinusoidal voltage and the low frequency RF voltage on the chuck and adjust the impedance of the VHF leg of the coupling source, i.e. the variable capacitor in the variable, impedance circuit 38. As shown in FIG. 1B, the VHF sinusoidal voltage is attenuated to near zero at the positive peak of the low frequency cycle. By adjusting the impedance of the VHF sinusoidal voltage source, it will vary the moment, or phase angle, in the low frequency RF voltage cycle at which the VHF voltage starts to be attenuated. So the magnitude of the attenuation will be determined.

The magnitude of the VHF sinusoidal voltage will also affect where the preferred operating range can be in the RF voltage cycle. If the magnitude of the VHF sinusoidal voltage is too large, the attenuation begins too close to the peak, while if the magnitude of the VHF sinusoidal voltage is too small, the attenuation begins too far away from the peak. So one can choose where on the low frequency RF voltage curve to operate by simply adjusting the impedance and the magnitude of the VHF sinusoidal voltage source. Thus the impedance of the VHF sinusoidal voltage is correlated in real time to the process shading damage. The adjustment of the impedance of the VHF source is done in a step by step systematic manner until the shading damage is eliminated or reduced to within an acceptable range. The adjustment, including its direction, can be defined by any conventional algorithm. For example, the variable capacitor in the variable impedance circuit 38 can be adjusted in small increments in either direction, the slope relating the change in voltage attenuation to change in capacitance can be evaluated in both directions, and the respective slope may then be utilized to determine the direction and magnitude of change required to adjust the attenuation level from the existing state to the desired state. Unlike the prior art where a timing control is required for every pulse, this invention only needs to establish the optimal impedance of the VHF source one time for each particular process. The adjustment of the VHF source impedance is visually based and easy to accomplish.

The invention still further provides a method for process analysis. One example could be process analysis for thin gate wafers. The apparatus, i.e., the VHF leg of the coupling circuit 12, can be initially adjusted to a given impedance value, a wafer can be processed and the thin gates on the wafer can be measured. Then, the impedance value can be changed, another wafer can be processed and the thin gates can again be measured. This sequence can be repeated any number of times until best impedance value is determined.

The invention still further provides a method for etching a wafer having high aspect ratio holes. Since the aspect ratio of the holes changes during a process, there may also be a variation of impedance of the VHF leg of the coupling circuit 12 throughout a run. The impedance variation throughout a run may be affected by the operator or pre-programmed. For example, the shading damage is worse at the end of a process than at the beginning. The process will need a higher circuit impedance as one goes further down into the holes. One will need to control both the output impedance of circuit 12 at the VHF frequency of the coupling circuit 12 and the magnitude of the VHF power, since they both affect the current-voltage curve (the I-V characteristic discussed earlier). It would be possible to vary the impedance and the amplitude of the VHF source as a function of the depth of the holes, which will be done based on time to achieve a better result. This can be done continuously or step by step in a systematic manner. Specifically, as hole depth increases, the impedance can be increased according to a predetermined function of time or depth. When the impedance is increased, the range over which the VHF voltage is appreciably attenuated, or suppressed, along the peak of the RF voltage cycle is increased. The VHF voltage magnitude, or the output power from the VHF generator would preferably be increased as the hole depth increases.

Thus, the impedance of the VHF portion of the coupling circuit and the magnitude of the VHF power are two controlling parameters. These two parameters can be individually controlled to reduce shading damage, or to obtain high etch rate. The control of these two parameters can be programmed to achieve a better etch result.

While the description above refers to particular embodiments of the present invention, it will be understood that many modifications may be made without departing from the spirit thereof. The accompanying claims are intended to cover such modifications as would fall within the true scope and spirit of the present invention.

The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

What is claimed is:

1. Apparatus for supplying a bias voltage to a wafer chuck in a plasma reactor system, comprising:
an RF voltage source producing a relatively low frequency RF voltage;
a VHF voltage source producing a VHF voltage having a higher frequency than the RF voltage; and
a coupling circuit connected between said RF and VHF voltage sources and the wafer chuck and combining the RF and VHF voltages for application to the wafer chuck.

2. The apparatus of claim 1 wherein said coupling circuit has a VHF voltage coupling portion connected to said VHF voltage source, said VHF voltage coupling portion having an output impedance which causes the VHF voltage applied to the chuck to be attenuated at positive peaks of the RF voltage.

3. The apparatus of claim 2 wherein the VHF voltage has a lower magnitude than the RF voltage.

4. The apparatus of claim 3 wherein said VHF voltage coupling portion comprises:
an output connected to the chuck; and
at least one impedance component connected between said VHF voltage source and said output.

5. The apparatus of claim 4 wherein said at least one impedance component has an adjustable impedance.

6. The apparatus of claim 5 wherein said at least one impedance component comprises a series arrangement of an inductor and a first capacitor connected in series between said VHF voltage source and said output and a second capacitor connected between said VHF voltage source and a point at ground potential.

7. The apparatus of claim 6 wherein said coupling circuit has a RF voltage coupling portion composed of a series arrangement of an inductor and a first capacitor connected in series between said VHF voltage source and said output and a second capacitor connected between said VHF voltage source and a point at ground potential.

8. The apparatus of claim 4 wherein the VHF voltage coupling portion includes an isolator and said at least one impedance component includes a series arrangement of an inductor and a capacitor.

9. The apparatus of claim 4 wherein the VHF voltage coupling portion includes an isolator and said at least one impedance component includes a matching network.

10. The apparatus of claim 9 wherein said coupling circuit includes a RF voltage coupling portion, said RF voltage coupling circuit including a matching network and a T-filter.

11. The apparatus of claim 10 wherein said T-filter includes first and second inductors connected in series and a capacitor having a first terminal connected to a junction between said first and second inductors and a second terminal connected to a point at ground potential.

12. The apparatus of claim 11 wherein said matching network of said VHF voltage coupling portion includes a first capacitor and an inductor connected in series, a second capacitor connected between a terminal of said first capacitor not connected to said inductor and a point at ground potential and a third capacitor connected between a terminal of said inductor not connected to said first capacitor and a point at ground potential.

13. The apparatus of claim 1 wherein each of the RF voltage and the VHF voltage has a sinusoidal waveform.

14. The apparatus of claim 1 wherein said VHF voltage source is adjustable to vary the magnitude of the VHF voltage.

15. A method for supplying a bias voltage to a wafer chuck in a plasma reactor system, comprising supplying a RF voltage and a VHF voltage having a higher frequency than the RF voltage to the chuck.

16. The method of claim 15 further comprising attenuating the VHF voltage at positive peaks of the RF voltage.

17. The method of claim 16 wherein the VHF voltage has a lower magnitude than the RF voltage.

18. The method of claim 17 wherein each of the RF voltage and the VHF voltage has a sinusoidal waveform.

19. The method of claim 16 further comprising varying the attenuation of the VHF voltage at the positive peaks of the RF voltage.

20. The method of claim 15 further comprising varying the amplitude of the VHF voltage.

21. The method of claim 15 wherein the RF voltage has a maximum voltage point at each positive peak and said method further comprises suppressing the VHF voltage during a portion of each RF voltage cycle that includes the maximum voltage peak.

22. A method for etching a workpiece comprising carrying out the method according to claim 21; forming an etching plasma in the reactor chamber; and varying the duration of the portion of each RF voltage cycle during which the VHF voltage is suppressed as the etching proceeds.
